(19) United States
(12) Patent Application Publication
(10) Pub. No.: US 2009/0302483 A1
(43) Pub. Date: Dec. 10, 2009

(54) STACKED DIE PACKAGE

(75) Inventors: Shih-Hsuan LIN, Tainan County (TW); Hung-Yi WANG, Tainan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX TECHNOLOGIES LIMITED, Tainan County (TW)

(21) Appl. No.: 12/132,788

(22) Filed: Jun. 4, 2008

(51) Int. Cl. H01L 23/00

(52) U.S. Cl. 257/777; 257/E23.001

(57) ABSTRACT

The invention provides a stacked die package. The package includes a lead frame having a plurality of the leads and a stack of dice disposed thereon, in which the upper die may be electrically connected to the leads via at least one transit area on the lower die to transfer a power signal or a ground signal.

### BACKGROUND OF THE INVENTION

1. Field of the Invention

The invention relates to electronic device packages, and more particularly to a stacked die package.

2. Description of the Related Art

Currently, semiconductor industry development goals are for higher performance, lower costs, increased miniaturization of components, and greater packaging density of integrated circuits. Greater integrated circuit density is primarily limited by the space available for mounting dice on a substrate such as a lead frame. One way to achieve greater integrated circuit density is by attaching two or more semiconductor dice or chips in a single semiconductor assembly.

Semiconductor dice can be stacked vertically to further increase integrated circuit density. For example, the dice may be stacked vertically atop each other prior to encapsulation. However, the power signal and the ground signal of the upper die can not be connected to the lead frame because of the restriction to the wire bond length and distance. Moreover, numerous power and ground signals may suppress the number of the leads used for control signals of the dice.

Thus, a stacked die package eliminating the described problems is needed.

### BRIEF SUMMARY OF INVENTION

Accordingly, the invention provides a stacked die package. An exemplary embodiment of the package includes: a substrate having a plurality of conductive areas; a first die having a plurality of first contact pads thereon and disposed on the substrate; a second die having a plurality of second contact pads thereon and disposed on the first die; and at least one transit area located near an edge of the first die, wherein a portion of second contact pads is electrically connected to the conductive areas via the transit area to transfer a power signal or a ground signal.

Also, the invention provides another exemplary embodiment of the package, which includes: a lead frame having a plurality of the leads; a first die having a plurality of first contact pads thereon and disposed on the lead frame; a second die having a plurality of second contact pads thereon and disposed on the first die; and at least one transit area located between the first contact pads and an edge of the first die, wherein the transit area includes at least one opening exposing a metal layer transferring a power signal or a ground signal of the second die.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1 to 2 are schematic views an electronic device according to a first embodiment of the invention;

FIG. 3 is a top view of an electronic device according to a second embodiment of the invention;

FIG. 4 is a top view of an electronic device according to a third embodiment of the invention;

FIG. 5 is a top view of an electronic device according to a fourth embodiment of the invention;

FIG. 6 is a top view of an electronic device according to a fifth embodiment of the invention.

### DETAILED DESCRIPTION OF INVENTION

The following description is of the exemplary embodiments of carrying out the invention. This description is made for the purpose of illustrating the general principles of the invention and should not be taken in a limiting sense. The scope of the invention is best determined by reference to the appended claims.

The invention will be described with respect to exemplary embodiments in specific context, namely a stacked die package using a lead frame, for example a package fabricated as a quad flat package (QFP), a low profile quad flat package (LQFP), a thin quad flat package (TQFP) package, etc. However, the invention may also be applied to a stacked die package fabricated as a ball grid array (BGA), a plastic ball grid array (PBGA) or a thin fine pitch ball grid array (TFBGA) package.

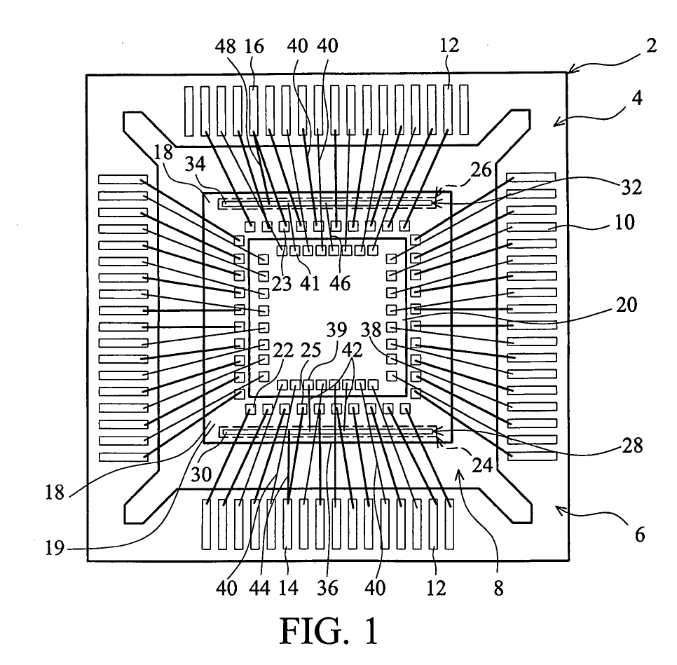

FIG. 1 is a top view of an electronic device 2 according to a first embodiment of the invention. Referring to FIG. 1, a substrate having a plurality of conductive areas, such as a lead frame 4, is provided. The lead frame 4 may be divided into a central area 8 and a peripheral area 6, on which there are a plurality of the leads 10 formed. A die 18, having a plurality of contact pads 22 thereon, is provided and disposed at the central area 8 of the lead frame 4 by attaching. A die 20, having a plurality of contact pads 38, is provided and disposed on the die 18 by attaching to form a stack. Moreover, the die 18 may also be referred to as a lower die and the die 20 may be referred to as an upper die.

In FIG. 1, transit areas 24 and 26 are formed on the surface 19 of the die 18. Preferably, the transit areas 24 and 26 are designed near the leads 10 for transferring signals. For example, the transit areas 24 and 26 are located at the periphery of the die 18 and between the contact pads 22 and the edges 36 of the die 18. The transit area 24 may include an opening 28, which exposes a metal layer 30, and the transit area 26 may include an opening 32, which exposes a metal layer 34, by which a portion of the contact pads 38 is electrically connected to the leads 10 to transfer a power signal and a ground signal, respectively.

As shown in FIG. 1, the leads 10 include the contact ends 12, in which a portion of the contact ends 12 used for transferring a power signal may be defined as the power bus 14, and the contact ends 12 used for transferring a ground signal may be defined as the ground bus 16. The contact pads 22 of the die 18 and the contact pads 38 of the die 20 may be electrically connected to the contact ends 12 via the wire bonds 40 to transmit their control signal. The contact pad 25 and the contact pad 23 of the die 18 may be electrically connected to the power bus 14 and the ground bus 16 via the wire bonds 40. For the die 20, the contact pad 39 may be electrically connected to the metal layer 30 of the transit area 24 via the wire bond 42, and then the metal layer 30 of the transit area 24 may be electrically connected to the power bus 14 via the wire bond 44, thereby transferring the power source to the die 20. Similarly, the contact pad 41 may be electrically connected to the metal layer 34 of the transit area 26 via the wire bond 46, and then the metal layer 34 of the transit area 26 may be electrically connected to the ground bus 16 via the wire bond 48, thereby transferring a ground signal from the die 20.

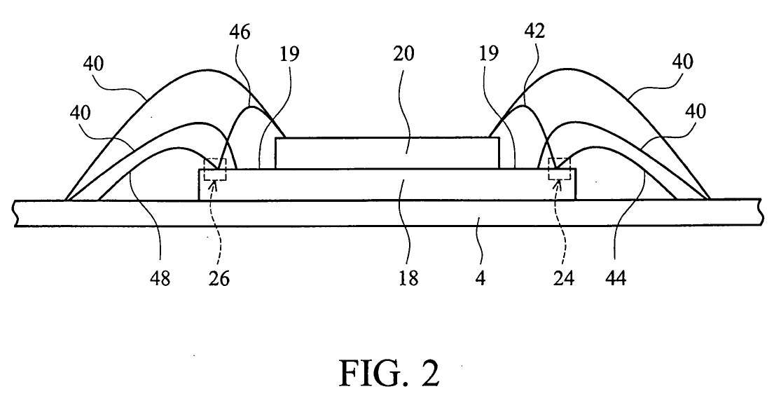

FIG. 2 is a side view of the electronic device 2 as shown in FIG. 1. Referring to FIG. 2, the stack of die 18 and die 20 is disposed on the lead frame 4. The power signal of the die 20 is transferred to the transit area 24, which is formed on the surface 19 of the die 18, and further to the power bus 14 of the lead frame 4 via the wire bonds 42 and 44. The ground signal of die 20 is transferred to the transit area 26, which is formed on the surface 19 of the die 18, and further to the ground bus 16 of the lead frame 4 via the wire bonds 46 and 48. Note that the transit area 24 may also be used for transferring a power signal, and in contrast, the transit area 26 may be used for transferring a ground signal.

Because the power and the ground signals of the upper die is transferred to the lead frame via the transit areas, which are formed on the lower die, problems caused by restrictions of the wire bond length and distance can be eliminated. Moreover, the number of power and ground signals can be accumulated at the transit areas, and then transferred to the power and the ground buses via a relatively few wire bonds. Thus, the number of leads serving as power or ground buses is decreased, such that the leads used for control signals of dice can be increased. Accordingly, design for the power bus and ground bus is more flexible.

In one embodiment, the transit areas 24 and 26 are fabricated during the same time as the contact pads 22. At first, the metal layers 30 and 34 made of a material, such as copper, aluminum or any other materials similar to the contact pads 22, are deposited and patterned during fabrication of the die 18. Next, a passivation layer (not symbolized), which covers the die 18 for protection, is partially removed to form the openings 28 and 32 exposing the metal layers 30 and 34 by etching. After the described steps, fabrication of the transit areas 24 and 26 are complete. Note that the metal layers 30 and 34 are independent and electrically isolated from the contact pads 22, respectively. Moreover, the electronic device 2 according to the first embodiment may be further encapsulated by a molding material to fabricate a stacked die package.

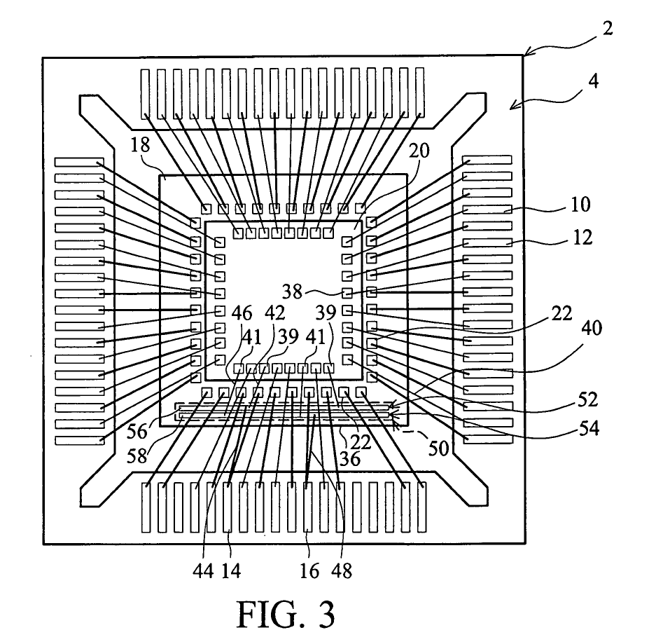

FIG. 3 is a top view of an electronic device 2 according to a second embodiment of the invention. The difference between the first and the second embodiments is the transit area. Thus, for similar elements, reference may be made to the descriptions in the first embodiment, and repeated details will not be provided here.

Referring to FIG. 3, the stack of the die 18 and the die 20 is disposed on the lead frame 4, and the power and the ground signals of the die 20 may be transferred to the leads of the lead frame 4 via the transit area 50, which is formed on the surface of the die 18. The transit area 50 according to the second embodiment is located at one side of the die 18 and between the contact pads 22 and the edge of the die 18. The transit area 50 includes two openings 52 and 54, which respectively exposes a metal layer 56 and a metal layer 58 for transferring power and ground signals.

In an embodiment, the contact pad 39 is electrically connected to the metal layer 56, and further to the power bus 14 of the leads 10 via the wire bonds 42 and 44 to transfer the power signal of the die 20. The contact pad 41 is electrically connected to the metal layer 58, and further to the ground bus 16 of the leads 10 via the wire bonds 46 and 48 to transfer the ground signal of the die 20. According to this case, the metal layer 58 for transferring the ground signal is nearer the edge 36 of the die 18 than the metal layer 56 for transferring the power signal. In an alternative embodiment (not shown), the metal layer 56 may also be used for transferring the ground signal, and the metal layer 58 may be used for transferring the power signal. That is, the metal layer 58 for transferring the power signal may be nearer the edge 36 of the die 20 than the metal layer 56 for transferring the ground signal. Accordingly, the above descriptions are only exemplary embodiments for carrying out the invention, but not limited thereto. Note that the metal layer for transferring the power signal and the metal layer for transferring the ground signal is electrically isolated from each other.

Since the power signal and the ground signal of the upper die is transferred via the transit area, which is formed on the lower die, problems caused by restrictions of the wire bond length and distance can be eliminated. Moreover, the number of leads serving as the power or the ground buses can be reduced, and utility efficiency of the leads used for control signals can be increased. Accordingly, design for the power bus and the ground bus is more flexible.

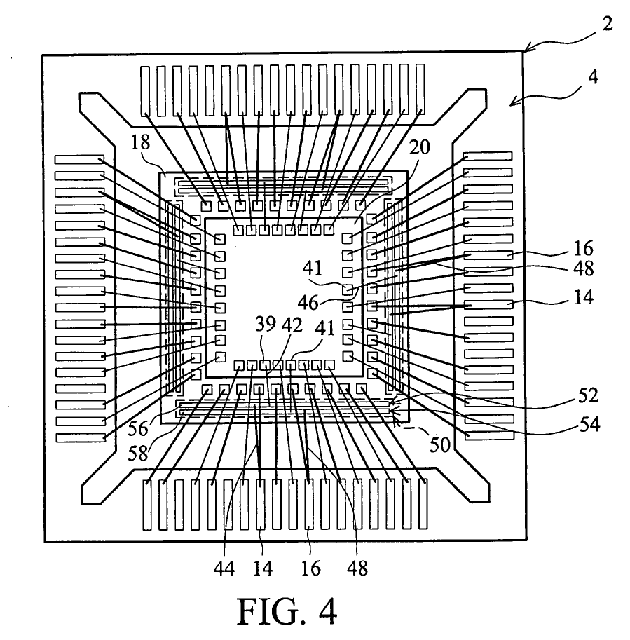

FIG. 4 is a top view of an electronic device 2 according to a third embodiment of the invention. Compared with the second embodiment, the transit area is disposed near each of the edges of the lower die and around the upper die. Thus, for similar elements, reference may be made to the descriptions in the first embodiment, and repeated details will not be provided here.

Referring to FIG. 4, transit areas 50 are disposed at each edge of the die 18, and each transit area 50 includes the opening 52, which exposes the metal layer 56, and the opening 54, which exposes the metal layer 58. The contact pads 41 may be electrically connected to the metal layer 58 via the wire bond 46, and the metal layer 58 may be electrically connected to the ground bus 16 via the wire bond 48 to transfer the ground signal of the die 20. The contact pads 39 may be electrically connected to the metal layer 56 via the wire bond 42, and then the metal layer 56 may be electrically connected to the power bus 14 via the wire bond 44 to transfer the power signal of the die 20. Similar to the second embodiment, the locations and connections of the metal layers can be exchanged for each other.

Since the power signal and the ground signal of the upper die is transferred via the transit areas, which are formed near the edges of the lower die, problems caused by restrictions of the wire bond length and distance can be eliminated. Note that the transit areas of the third embodiment may include a single opening exposing a metal layer to transfer the power signal or the ground signal.

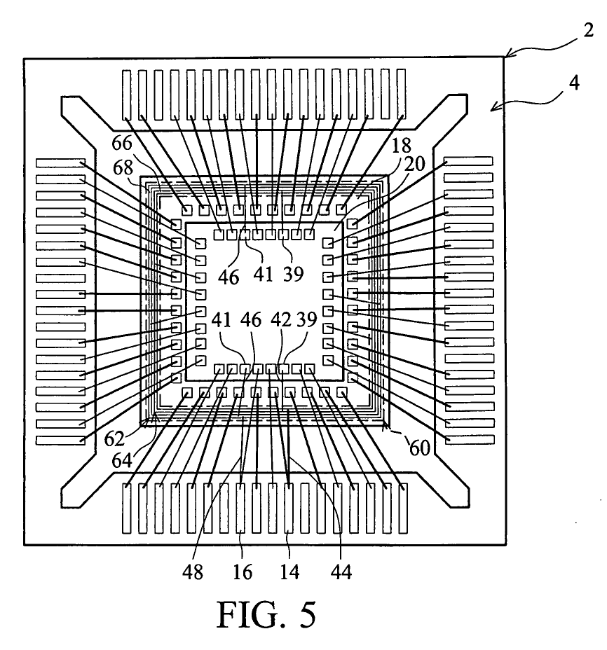

FIG. 5 is a top view of an electronic device 2 of a fourth embodiment of the invention. Compared with the third embodiment, the transit area is a ring shape around the upper die.

Referring to FIG. 5, the transit area 60 is a ring shape and includes the opening 62, which exposes the metal layer 68, and the opening 64, which exposes the metal layer 66. The contact pads 39 are electrically connected to the metal layer 66 and further to the power bus 14 via the wire bonds 42 and 44 to transfer the power signal of the die 20. The contact pads 41 are electrically connected to the metal layer 68 and further to the ground bus 16 via the wire bonds 46 and 48 to transfer the ground signal of the die 20. Moreover, since the transit area may be designed as a ring shape, the power and the ground buses may be disposed at only one side of the lead frame. Thus, leads serving as the power and the ground buses can be reduced, and leads transferring control signals can be increased. In addition, the locations and connections of the metal layers may also be exchanged.

Because the power signal and the ground signal of the upper die is transferred via the transit area, which is formed on the surface of the lower die, problems caused by restrictions of the wire bond length and distance can be eliminated. Note that the transit area of the fourth embodiment, which includes a single opening exposing a metal layer to transfer the power signal or the ground signal, may also be possible.

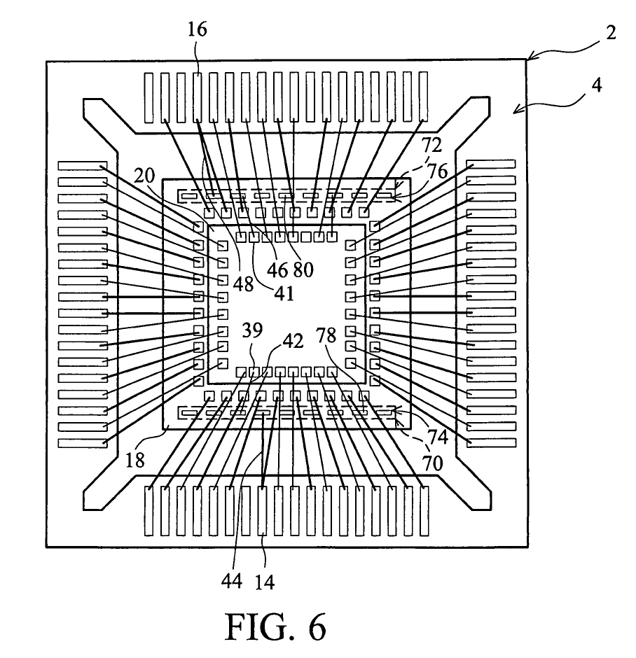

FIG. 6 is a top view of an electronic device 2 according to a fifth embodiment of the invention. In this case, the transit area may include a plurality of openings, which expose a metal layer for transferring the power signal or the ground signal of the upper die. Thus, for similar elements, reference may be made to the previous descriptions, and repeated details will not be provided here.

Referring to FIG. 6, the stack of the die 18 and the die 20 is disposed on the lead frame 4, and the power signal and the ground signal of the die 20 is transferred to the lead frame 4 via the transit areas 70 and 72, which are formed on the die 18. The transit areas 70 and 72 include the plurality of the openings 74 and 76, which exposes the metal layer 78 and the metal layer 80, respectively. The contact pads 39 are electrically connected to the metal layer 78 and further to the power bus 14 via the wire bonds 42 and 44 to transfer the power signal of the die 20. The contact pads 41 are electrically connected to the metal layer 80 and further to the ground bus 16 via the wire bonds 46 and 48 to transfer the ground signal of the die 20.

It is appreciated that the transit area in this embodiment may be numerous and respectively disposed at each edge of the lower die, or a ring shape to surround the upper die. Moreover, the transit area may also include two metal layers, in which one is used for transferring the power signal and the other is used for transferring the ground signal. Note that the electronic devices of the second to fifth embodiments may also be encapsulated by a molding material to form stacked die packages.

Because the power signal and the ground signal of the upper die is transferred via the transit area, which is formed at each edge of the lower die, problems caused by restrictions of the wire bond length and distance can be eliminated. Moreover, number of power and ground signals can be accumulated at the transit areas, and then transferred to the power and the ground buses via a relatively few wire bonds. Thus, the number of leads serving as power or ground buses can be decreased, thereby increasing the leads used for control signals.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A stacked die package, comprising:
a substrate having a plurality of conductive areas;
a first die having a plurality of first contact pads thereon and disposed on the substrate;
a second die having a plurality of second contact pads thereon and disposed on the first die; and
at least one transit area located near an edge of the first die, wherein a portion of the second contact pads is electrically connected to the conductive areas via the transit area to transfer a power signal or a ground signal.

2. The package as claimed in claim 1, wherein the transit area comprises at least one opening exposing a metal layer transferring a power signal or a ground signal of the second die.

3. The package as claimed in claim 2, further comprising:
a plurality of first wire bonds electrically connected to the second contact pads to the metal layer; and
a plurality of second wire bonds electrically connected to the metal layer to the conductive areas.

4. The package as claimed in claim 2, wherein the transit area is disposed at each edge of the first die to surround the second die.

5. The package as claimed in claim 2, wherein the transit area comprises a ring shape around the second die.

6. The package as claimed in claim 2, wherein the transit area comprises a plurality of the openings exposing the metal layer.

7. The package as claimed in claim 2, wherein the transit area comprises:
a first opening exposing a first metal layer transferring a power signal of the second die; and
a second opening exposing a second metal layer transferring a ground signal of the second die.

8. The package as claimed in claim 1, wherein the transit area is disposed between the first contact pads and the edge of the first die.

9. A stacked die package, comprising:
a lead frame having a plurality of the leads;
a first die having a plurality of first contact pads thereon and disposed on the lead frame;
a second die having a plurality of second contact pads thereon and disposed on the first die;
at least one transit area located between the first contact pads and an edge of the first die, wherein the transit area comprises at least one opening exposing a metal layer transferring a power signal or a ground signal of the second die.

10. The package as claimed in claim 9, further comprising:
a plurality of first wire bonds electrically connected to a portion of the second contact pad to the metal layer; and
a plurality of second wire bonds electrically connected to the metal layer to the leads.

11. The package as claimed in claim 9, wherein the transit area is disposed at the each edge of the first die to surround the second die.

12. The package as claimed in claim 9, wherein the transit area comprises a ring shape around the second die.

13. The package as claimed in claim 9, wherein the transit area comprises a plurality of the openings exposing the metal layer.

14. The package as claimed in claim 9, wherein the transit area comprises:
a first opening exposing a first metal layer transferring a power signal of the second die; and
a second opening exposing a second metal layer transferring a ground signal of the second die.
